(19) United States
(12) Patent Application Publication
(10) Pub. No.: US 2021/0403494 A1
(43) Pub. Date: Dec. 30, 2021

(54) ELECTROLUMINESCENT MATERIAL, METHOD FOR MANUFACTURING SAME, AND LIGHT EMITTING DEVICE

(71) Applicant: Wuhan China Star Optoelectronics Semiconductor Display Technology Co., Ltd., Wuhan, Hubei (CN)

(72) Inventor: Yamin Wang, Wuhan, Hubei (CN)

(21) Appl. No.: 16/608,599

(22) PCT Filed: Jul. 10, 2019
(86) PCT No.: PCT/CN2019/095411

§ 371 Date: Oct. 25, 2019

(30) Foreign Application Priority Data
Apr. 29, 2019 (CN) 201910359594.8

(51) Int. Cl. C07F 9/53; H01L 51/00

(52) U.S. Cl. CPC C07F 9/5329; H01L 51/56; H01L 51/0052

(57) ABSTRACT

The present application provides an electroluminescent material, a method for manufacturing the electroluminescent material, and a light emitting device, by employing an anthracene group and a triphenylphosphine oxide group, applying the molecule containing the anthracene group showing an excellent light emitting characteristic and two electron-deficient triphenylphosphine oxide groups located at the 6-position and 13-position of the anthracene group, an electroluminescent material, a method for manufacturing the electroluminescent material and a light emitting device with a blue light emitted and high luminous efficiency are achieved.

### BACKGROUND OF INVENTION

### Field of Invention

The present application relates to a display field, and particularly to an electroluminescent material, a method for manufacturing the electroluminescent material, and a light emitting device.

### Description of Prior Art

In the prior art, organic light emitting diodes (OLEDs) have self-luminous properties, and a material that mainly dominates light-emitting is electroluminescent material. However, luminous efficiency of the existing electroluminescent material is poor, which often leads to failure of the organic light emitting diodes, therefore, it is necessary to provide an electroluminescent material, a method for manufacturing the electroluminescent material, and a light emitting device with a high luminous efficiency.

### SUMMARY OF INVENTION

The present application provides an electroluminescent material, a method for manufacturing the electroluminescent material, and a light emitting device.

The present application provides an electroluminescent material, a structural formula of the electroluminescent material comprises one

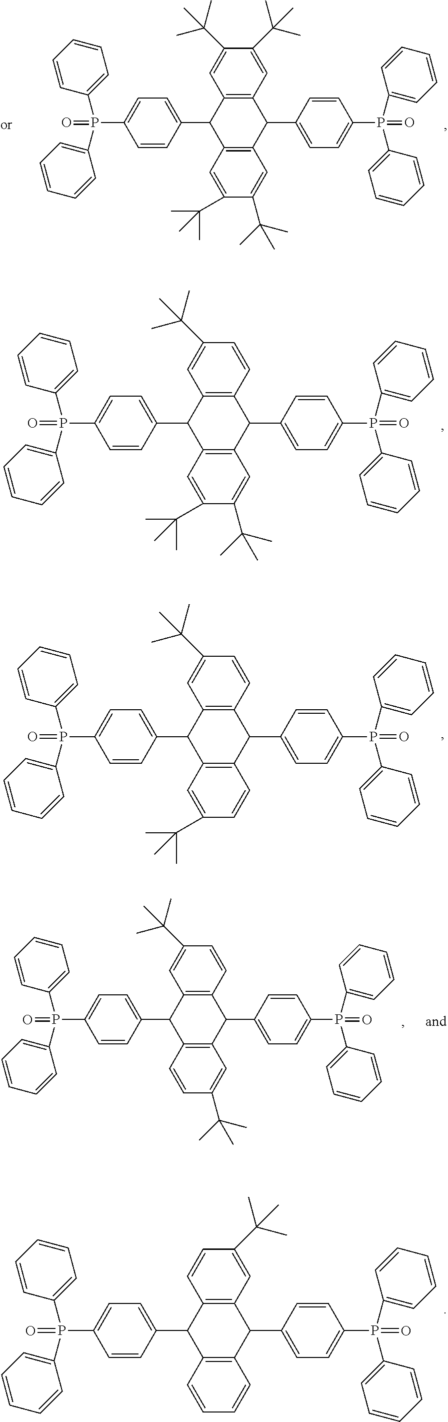

The present application also provides a method for manufacturing an electroluminescent material, comprising:

providing a first reactant and a second reactant, and reacting the first reactant and the second reactant in a first reaction solution to generate a first intermediate product, wherein a structural formula of the first reactant comprises one

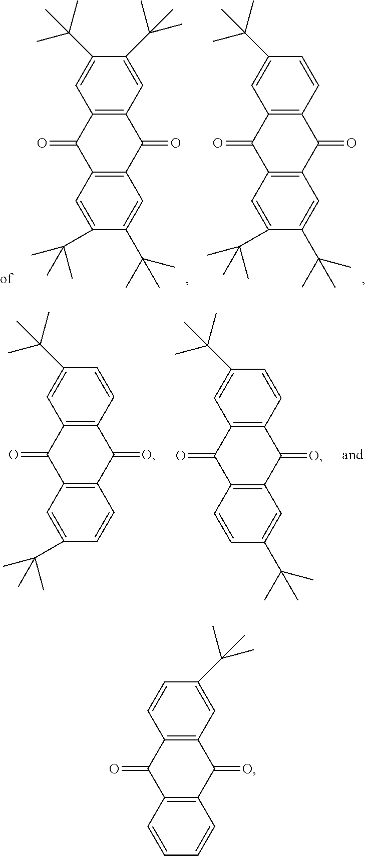

a structural formula of the second reactant comprises

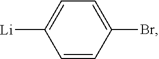

a structural formula of the first intermediate product comprises one of

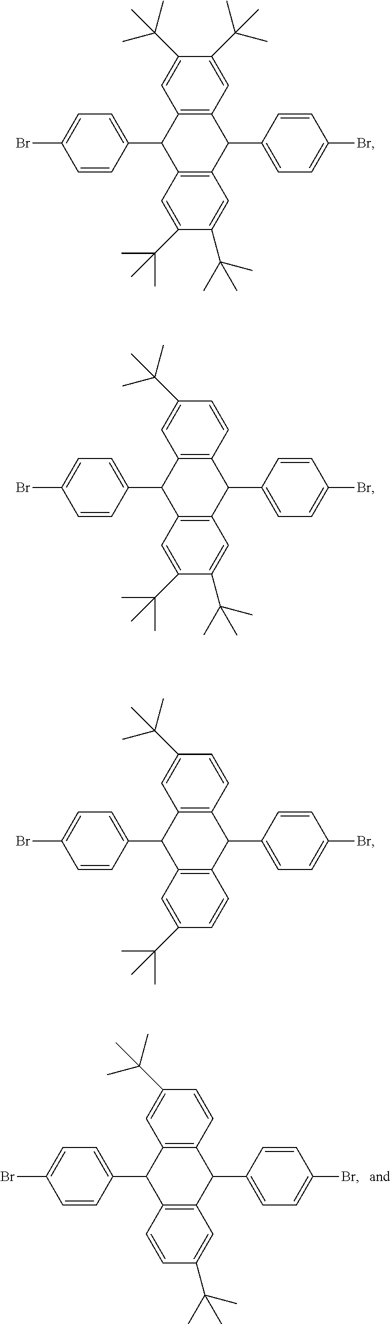 [SMILES: CC(C)(C)c1cc2c(cc1C(C)(C)C)C(c1ccc(Br)cc1)c1cc(C(C)(C)C)c(C(C)(C)C)cc1C2c1ccc(Br)cc1 ; CC(C)(C)c1ccc2c(c1)C(c1ccc(Br)cc1)c1cc(C(C)(C)C)c(C(C)(C)C)cc1C2c1ccc(Br)cc1 ; CC(C)(C)c1ccc2c(c1)C(c1ccc(Br)cc1)c1cc(C(C)(C)C)ccc1C2c1ccc(Br)cc1 ; CC(C)(C)c1ccc2c(c1)C(c1ccc(Br)cc1)c1ccc(C(C)(C)C)cc1C2c1ccc(Br)cc1 ; "and"]

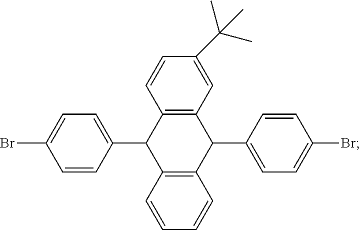 [SMILES: CC(C)(C)c1ccc2c(c1)C(c1ccc(Br)cc1)c1ccccc1C2c1ccc(Br)cc1]

and

providing a third reactant, and reacting the third reactant and the first intermediate product with an oxidant to generate the electroluminescent material, wherein a structural formula of the third reactant is

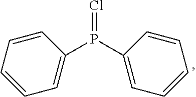

a structural formula of the electroluminescent material comprises one of

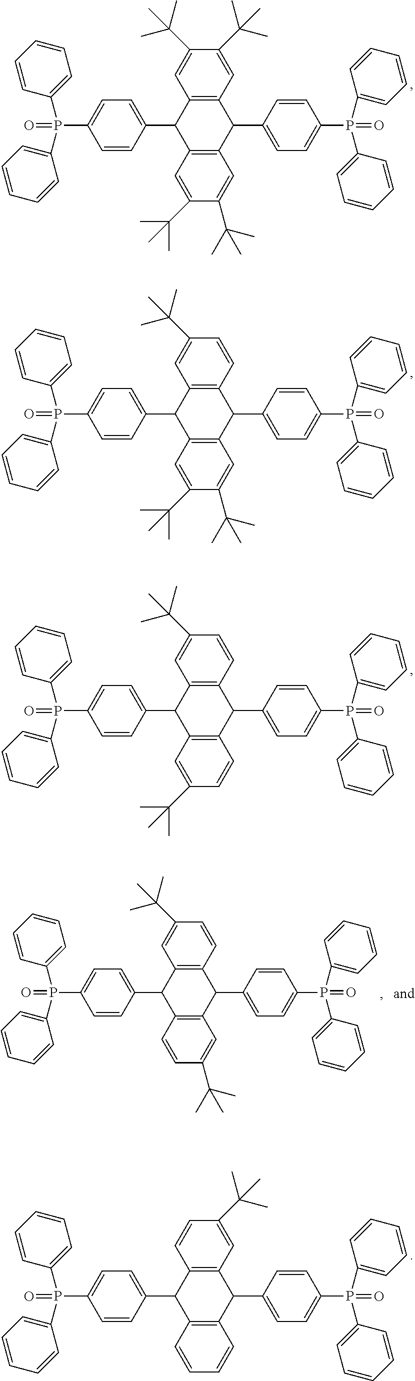

In the method for manufacturing the electroluminescent material, the step of providing a first reactant and a second reactant, and reacting the first reactant and the second reactant in a first reaction solution to generate a first intermediate product, comprising:

providing a first reactant and a second reactant, and reacting the first reactant and the second reactant in a first reaction solution to generate a first mixture containing a first intermediate product; and

separating and purifying the mixture containing the first intermediate product, and then dissolving in a first solvent to obtain a second mixture containing the first intermediate product.

In the method for manufacturing the electroluminescent material, in the step of providing a third reactant, and reacting the third reactant and the first intermediate product with an oxidant to generate the electroluminescent material, at a first temperature, a solution containing a catalyst is slowly added into the second mixture, then the third reactant is dropwise added, a reaction temperature is maintained below a second temperature, a stirring and reacting process is employed.

In the method for manufacturing the electroluminescent material, the first temperature is −10 degrees Celsius to 150 degrees Celsius.

In the method for manufacturing the electroluminescent material, the first temperature is −30 degrees Celsius to 100 degrees Celsius.

In the method for manufacturing the electroluminescent material, the second temperature is 60 degrees Celsius.

In the method for manufacturing the electroluminescent material, in the step of providing a third reactant, and reacting the third reactant and the first intermediate product with an oxidant to generate the electroluminescent material, a relationship between a molar quantity of the third reactant and a molar quantity of the first intermediate product is that for 2 millimoles-20 millimoles of the third reactant, there are 1 millimole-10 millimoles of the first intermediate product.

In the method for manufacturing the electroluminescent material, a relationship between a volume of the first solvent and a molar quantity of the first intermediate product is that for 10 milliliters-300 milliliters of the first solvent, there are 1 millimole-10 millimoles of the first intermediate product.

In the method for manufacturing the electroluminescent material, the first solvent is tetrahydrofuran.

In the method for manufacturing the electroluminescent material, the first reaction solution comprises water.

In the method for manufacturing the electroluminescent material, the solution containing the catalyst is a solution containing a catalyst n-BuLi.

The present application also provides a light emitting device, comprising:

a substrate layer, wherein the substrate layer includes a base and an anode layer, the anode layer is formed on the base;

a hole injection layer, wherein the hole injection layer is formed on the anode layer;

a hole transport layer, wherein the hole transport layer is formed on the hole injection layer;

a light emitting layer, wherein the light emitting layer is formed on the hole transport layer;

an electron injection layer, wherein the electron injection layer is formed on the light emitting layer; and

a cathode layer, wherein the cathode layer is formed on the electron injection layer;

wherein the light emitting layer comprises the electroluminescent material, wherein a structural formula of the electroluminescent material comprises one of

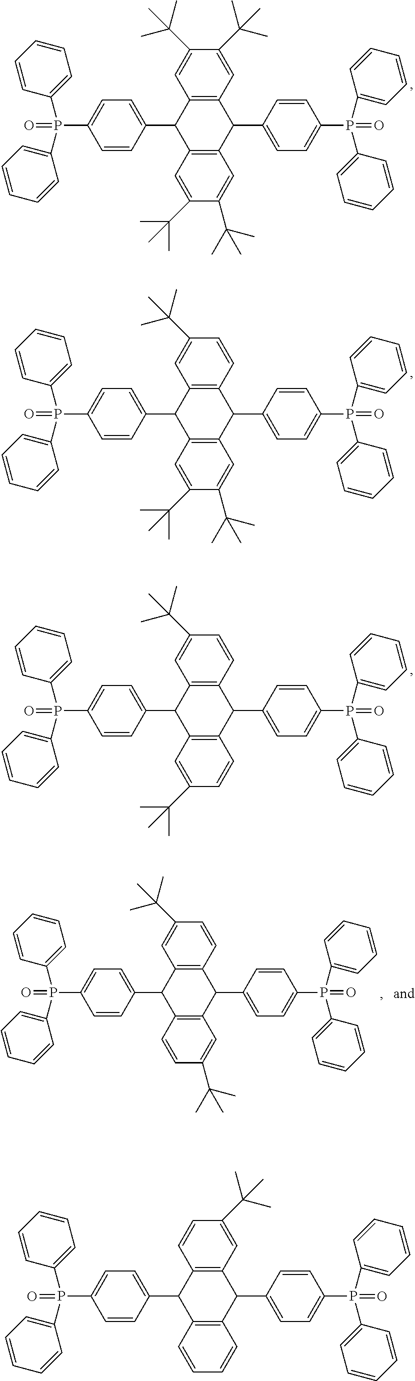

The benefit is: the present application provides an electroluminescent material, a method for manufacturing the electroluminescent material, and a light emitting device, by employing an anthracene group and a triphenylphosphine oxide group, applying the molecule containing the anthracene group showing an excellent light emitting characteristic and two electron-deficient triphenylphosphine oxide groups located at the 6-position and 13-position of the anthracene group, the non-coplanar conformation effectively prevents filling, excimer formation, and fluorescence quenching of closely molecules in the solid state, an electroluminescent material, a method for manufacturing the electroluminescent material and a light emitting device with a blue light emitted and high luminous efficiency are achieved.

### BRIEF DESCRIPTION OF DRAWINGS

In order to more clearly illustrate the technical solutions in the present application, the drawings used in the description of the embodiments will be briefly described below. It is obvious that the drawings in the following description are only some embodiments of the present application, those skilled in the art can also obtain other drawings based on these drawings without paying creative labor.

FIG. 1 is an electroluminescent spectrum of an electroluminescent material

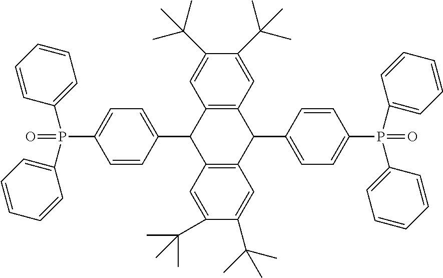 [SMILES: CC(C)(C)c1cc2c(cc1C(C)(C)C)C(c1ccc(P(=O)(c3ccccc3)c3ccccc3)cc1)c1cc(C(C)(C)C)c(C(C)(C)C)cc1C2c1ccc(P(=O)(c2ccccc2)c2ccccc2)cc1]

of the present application in a liquid sate and in a film state.

FIG. 2 is a schematic structural view of a light emitting device of the present application.

### DETAILED DESCRIPTION OF PREFERRED EMBODIMENTS

The technical solutions in the present application will be clearly and completely described in the following with reference to the accompanying drawings in the embodiments of the present application. It is apparent that the described embodiments are only a part of the embodiments of the present application, and not all of them. All other embodiments obtained by a person skilled in the art based on the embodiments in the present application without creative efforts are within the scope of the present application.

The present application provides an electroluminescent material, a structural formula of the electroluminescent material includes one of

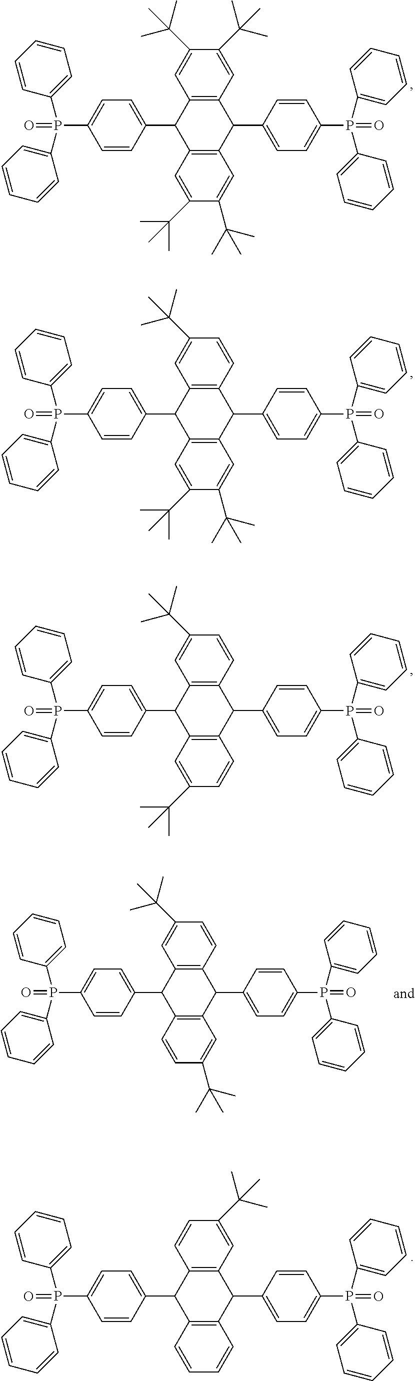

The electroluminescent material is a blue light emitting electroluminescent material.

The present application also provides a method for manufacturing the electroluminescent material. The method for manufacturing the electroluminescent material includes:

A, providing a first reactant and a second reactant, and reacting the first reactant and the second reactant in a first reaction solution to generate a first intermediate product, wherein a structural formula of the first reactant comprises one of

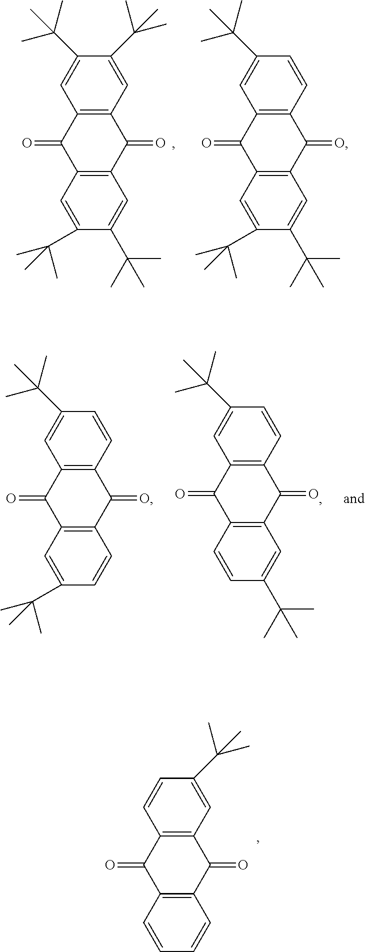

a structural formula of the second reactant comprises

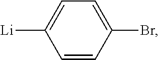

a structural formula of the first intermediate product comprises one of

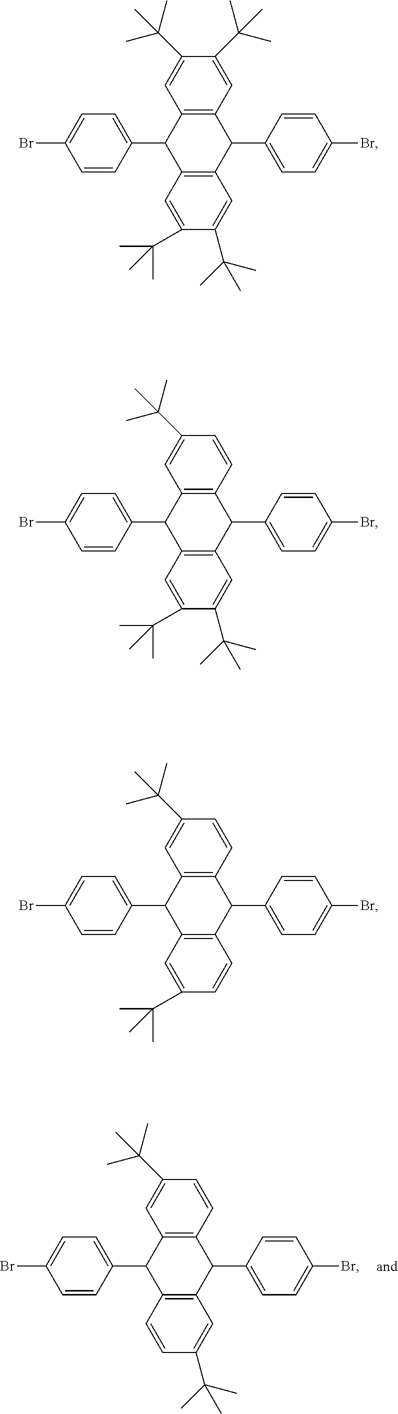 [SMILES: CC(C)(C)c1cc2c(cc1C(C)(C)C)C(c1ccc(Br)cc1)c1cc(C(C)(C)C)c(C(C)(C)C)cc1C2c1ccc(Br)cc1 ; CC(C)(C)c1ccc2c(c1)C(c1ccc(Br)cc1)c1cc(C(C)(C)C)c(C(C)(C)C)cc1C2c1ccc(Br)cc1 ; CC(C)(C)c1ccc2c(c1)C(c1ccc(Br)cc1)c1cc(C(C)(C)C)ccc1C2c1ccc(Br)cc1 ; CC(C)(C)c1ccc2c(c1)C(c1ccc(Br)cc1)c1ccc(C(C)(C)C)cc1C2c1ccc(Br)cc1]

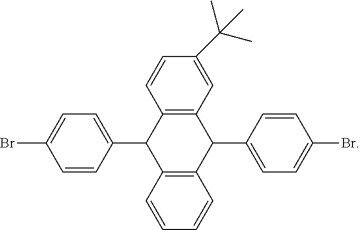 [SMILES: CC(C)(C)c1ccc2c(c1)C(c1ccc(Br)cc1)c1ccccc1C2c1ccc(Br)cc1]

The step of providing a first reactant and a second reactant, and reacting the first reactant and the second reactant in a first reaction solution to generate a first intermediate product can includes:

providing a first reactant and a second reactant, and reacting the first reactant and the second reactant in a first reaction solution to generate a first mixture containing a first intermediate product; separating and purifying the mixture containing the first intermediate product, and then dissolving in a first solvent to obtain a second mixture containing the first intermediate product. The first reaction solution can include water.

A relationship between a volume of the first solvent and a molar quantity of the first intermediate product is that for 10 milliliters-300 milliliters of the first solvent, there are 1 millimole-10 millimoles of the first intermediate product. In some embodiments, a relationship between a volume of the first solvent and a molar quantity of the first intermediate product can be that for 50 milliliters of the first solvent, there are 3 millimoles of the first intermediate product. A relationship between a volume of the first solvent and a molar quantity of the first intermediate product also can be that for 200 milliliters of the first solvent, there are 8 millimoles of the first intermediate product.

In one embodiment, the first reactant is

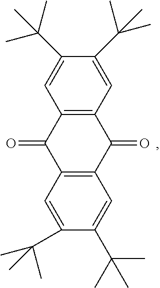 [SMILES: CC(C)(C)c1cc2c(cc1C(C)(C)C)C(=O)c1cc(C(C)(C)C)c(C(C)(C)C)cc1C2=O]

the first reactant and the second reactant are reacted in a first reaction solution to generate a first intermediate product is:

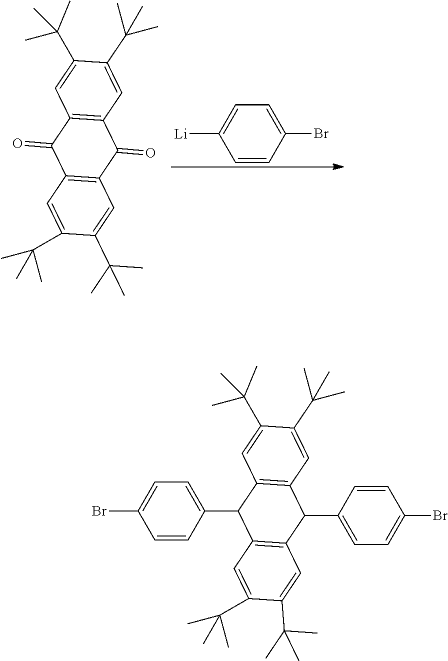

B, providing a third reactant, and reacting the third reactant and the first intermediate product with an oxidant to generate the electroluminescent material, wherein a structural formula of the third reactant is

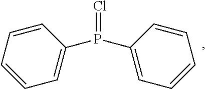

a structural formula of the electroluminescent material comprises one of

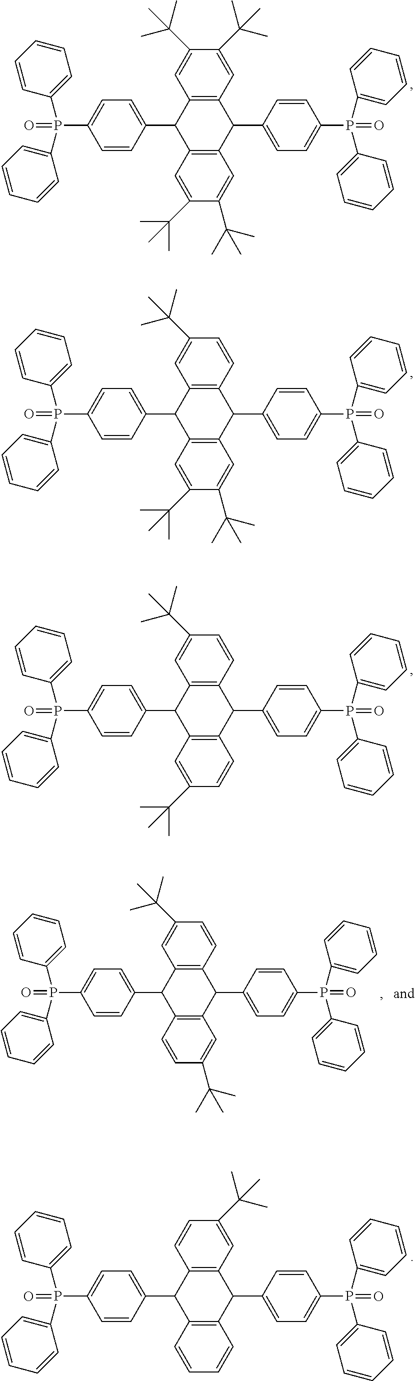

In the step of providing a third reactant, and reacting the third reactant and the first intermediate product with an oxidant to generate the electroluminescent material, at a first temperature, a solution containing a catalyst is slowly added into the second mixture, then the third reactant is dropwise added, a reaction temperature is maintained below a second temperature, a stirring and reacting process is employed. The first temperature is −10 degrees Celsius to 150 degrees Celsius. The second temperature is 60 degrees Celsius. A molar quantity of the third reactant and a molar quantity of the first intermediate product are 2 millimoles-20 millimoles of the third reactant corresponding to 1 millimole-10 millimoles of the first intermediate product.

In one embodiment, as the first temperature of −30 degrees Celsius to 100 degrees Celsius, in an argon atmosphere, 2 milliliters-10 milliliters of a solution containing a catalyst n-BuLi are slowly added into 10 milliliters-300 milliliters of a solution tetrahydrofuran containing 1 millimole-10 millimoles of the first intermediate product, 2 millimole-20 millimoles of the third reactant

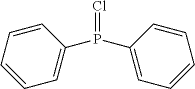

is dropwise added, at the same time, a reaction solution temperature is maintained below the second temperature 60 degrees Celsius, the reaction solution is gradually changed to light yellow color, then the reaction solution is cooled down to a room temperature and stirred for 3 hours-24 hours, and separated and purified to achieve the electroluminescent material

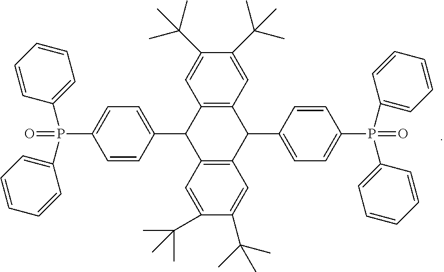 [SMILES: CC(C)(C)c1cc2c(cc1C(C)(C)C)C(c1ccc(P(=O)(c3ccccc3)c3ccccc3)cc1)c1cc(C(C)(C)C)c(C(C)(C)C)cc1C2c1ccc(P(=O)(c2ccccc2)c2ccccc2)cc1]

In the step of separating and purifying, first, the reaction mixture is quenched by a deionized water, then extracted by an ethyl acetate to obtain an organic phase, then the organic phase is dried by MgSO₄ and concentrated on a negative pressure, a remaining product is dissolved into the CH₂Cl₂ and the oxidant solution is added, a stirring process is employed for 1 hour at a room temperature, an organic phase is collected, and then the organic phase is dried by MgSO₄ and concentrated on a negative pressure again, a separating and purifying process is employed to obtain the electroluminescent material

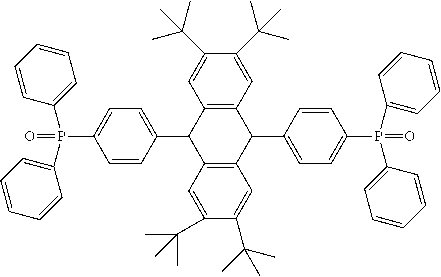 [SMILES: CC(C)(C)c1cc2c(cc1C(C)(C)C)C(c1ccc(P(=O)(c3ccccc3)c3ccccc3)cc1)c1cc(C(C)(C)C)c(C(C)(C)C)cc1C2c1ccc(P(=O)(c2ccccc2)c2ccccc2)cc1]

by a column chromatography.

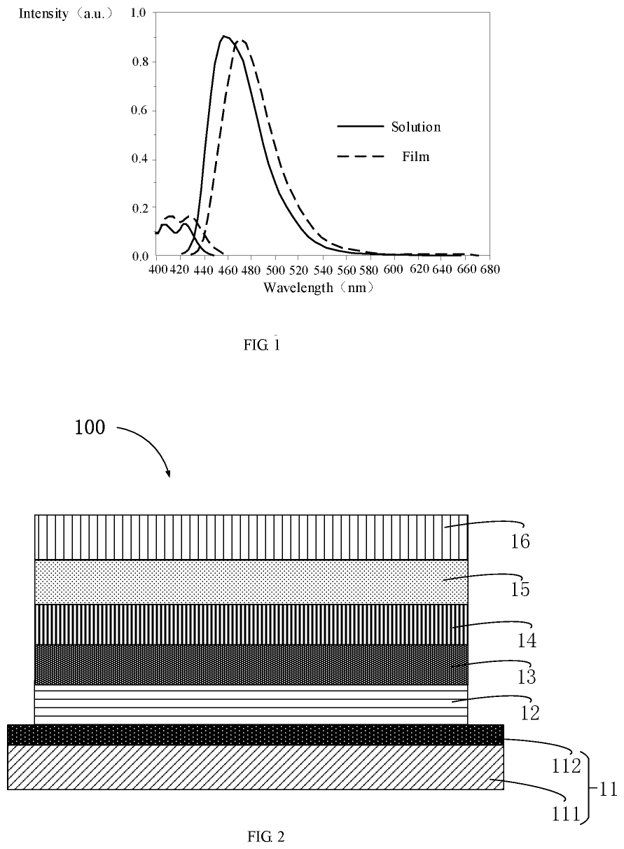

Referring to FIG. 1, FIG. 1 is an electroluminescent spectrum of an electroluminescent material

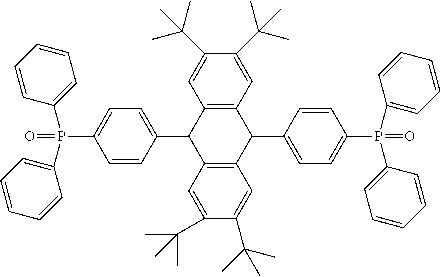 [SMILES: CC(C)(C)c1cc2c(cc1C(C)(C)C)C(c1ccc(P(=O)(c3ccccc3)c3ccccc3)cc1)c1cc(C(C)(C)C)c(C(C)(C)C)cc1C2c1ccc(P(=O)(c2ccccc2)c2ccccc2)cc1]

of the present application in a liquid sate and in a film state. The maximum emitting peak of the electroluminescent material

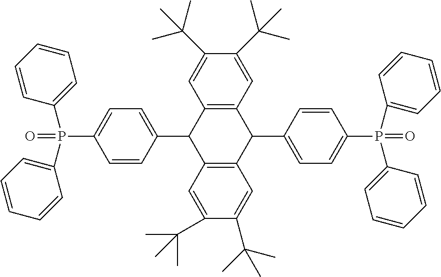 [SMILES: CC(C)(C)c1cc2c(cc1C(C)(C)C)C(c1ccc(P(=O)(c3ccccc3)c3ccccc3)cc1)c1cc(C(C)(C)C)c(C(C)(C)C)cc1C2c1ccc(P(=O)(c2ccccc2)c2ccccc2)cc1]

in a liquid is located at 456 nm, the maximum emitting peak of the electroluminescent material

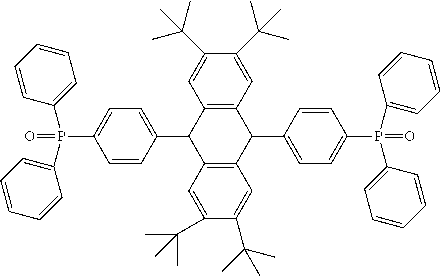 [SMILES: CC(C)(C)c1cc2c(cc1C(C)(C)C)C(c1ccc(P(=O)(c3ccccc3)c3ccccc3)cc1)c1cc(C(C)(C)C)c(C(C)(C)C)cc1C2c1ccc(P(=O)(c2ccccc2)c2ccccc2)cc1]

in a film state is located at 479 nm. The electroluminescent material is blue light emitting material.

Referring to FIG. 2, FIG. 2 is a schematic structural view of a light emitting device 100 of the present application. The light emitting device 100 includes a substrate layer 11, a hole injection layer 12, a hole transport layer 13, a light emitting layer 14, an electron injection layer 15, and a cathode layer 16.

The substrate layer 11 includes a base 111 and an anode layer 112. The base 111 can be a glass base or a transparent plastic base. The anode layer 112 is formed on the base 111. The anode layer 112 can be made of indium tin oxide. The hole injection layer 12 is formed on the anode layer 112. The hole transport layer 13 is formed on the hole injection layer 12. The light emitting layer 14 is formed on the hole transport layer 13. The light emitting layer 14 includes the electroluminescent material, a structural formula of the electroluminescent material includes one of

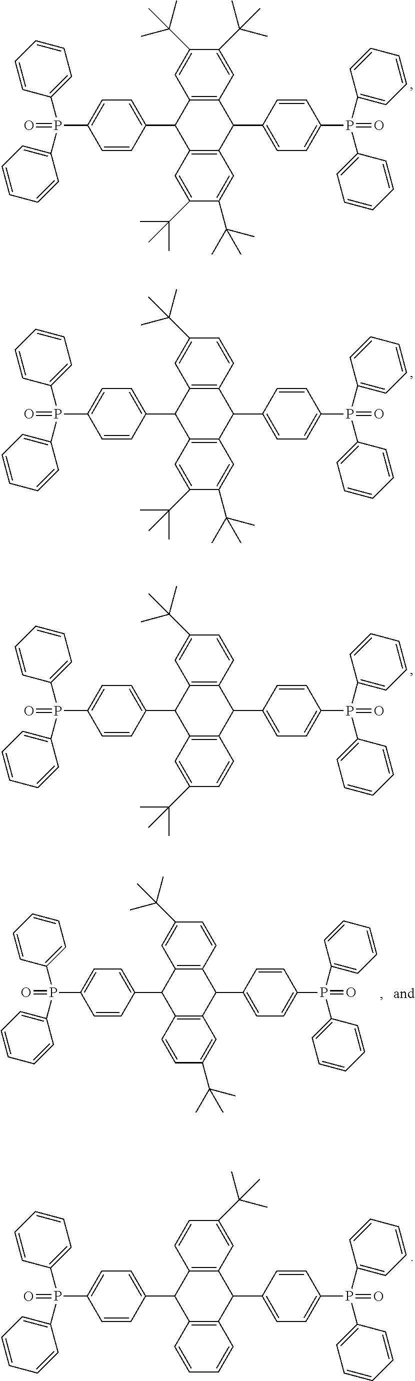

The electron injection layer 15 is formed on the light emitting layer 14. The cathode layer 16 is formed on the electron injection layer 15. The cathode layer 16 can be made of lithium fluoride/aluminum.

The present application provides an electroluminescent material, a method for manufacturing the electroluminescent material, and a light emitting device, by employing an anthracene group and a triphenylphosphine oxide group, applying the molecule containing the anthracene group showing an excellent light emitting characteristic and two electron-deficient triphenylphosphine oxide groups located at the 6-position and 13-position of the anthracene group, the non-coplanar conformation effectively prevents filling, excimer formation, and fluorescence quenching of closely molecules in the solid state, an electroluminescent material, a method for manufacturing the electroluminescent material and a light emitting device with a blue light emitted and high luminous efficiency are achieved.

The embodiments of the present application are described in detail above, and the principles and implementations of the present application are set forth in the specific examples. The description of the above embodiments is only for helping to understand the present application. In the meantime, those skilled in the art will be able to change the specific embodiments and the scope of the application according to the idea of the present application. In the above, the content of the specification should not be construed as limiting the present application.

What is claimed is:

1. An electroluminescent material, wherein a structural formula of the electroluminescent material comprises one of

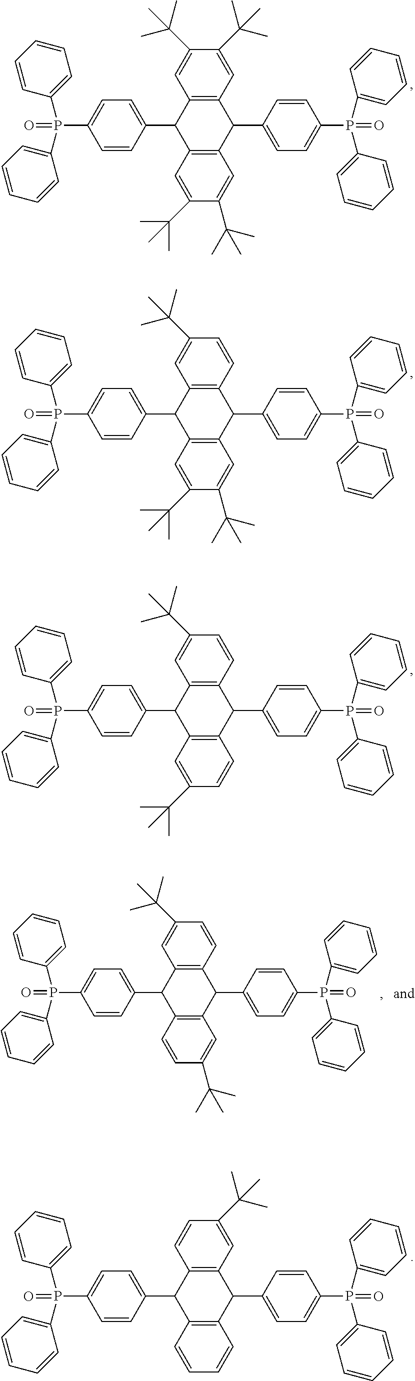

2. A method for manufacturing an electroluminescent material, comprising:
providing a first reactant and a second reactant, and reacting the first reactant and the second reactant in a first reaction solution to generate a first intermediate product, wherein a structural formula of the first reactant comprises one of 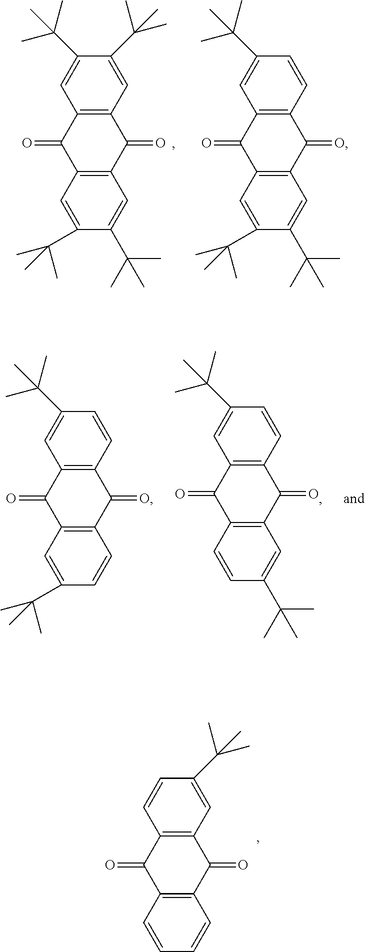
a structural formula of the second reactant comprises 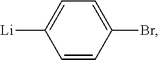
a structural formula of the first intermediate product comprises one of 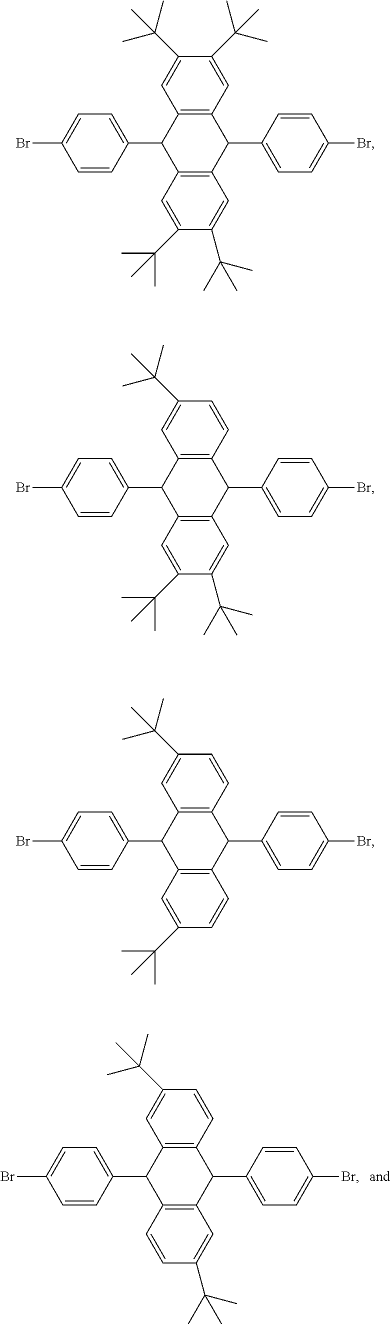 [SMILES: CC(C)(C)c1cc2c(cc1C(C)(C)C)C(c1ccc(Br)cc1)c1cc(C(C)(C)C)c(C(C)(C)C)cc1C2c1ccc(Br)cc1 ; CC(C)(C)c1ccc2c(c1)C(c1ccc(Br)cc1)c1cc(C(C)(C)C)c(C(C)(C)C)cc1C2c1ccc(Br)cc1 ; CC(C)(C)c1ccc2c(c1)C(c1ccc(Br)cc1)c1cc(C(C)(C)C)ccc1C2c1ccc(Br)cc1 ; CC(C)(C)c1ccc2c(c1)C(c1ccc(Br)cc1)c1ccc(C(C)(C)C)cc1C2c1ccc(Br)cc1 ; "and"] 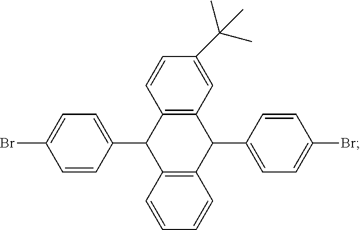 [SMILES: CC(C)(C)c1ccc2c(c1)C(c1ccc(Br)cc1)c1ccccc1C2c1ccc(Br)cc1]
and
providing a third reactant, and reacting the third reactant and the first intermediate product with an oxidant to generate the electroluminescent material, wherein a structural formula of the third reactant is 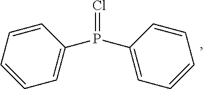
a structural formula of the electroluminescent material comprises one of

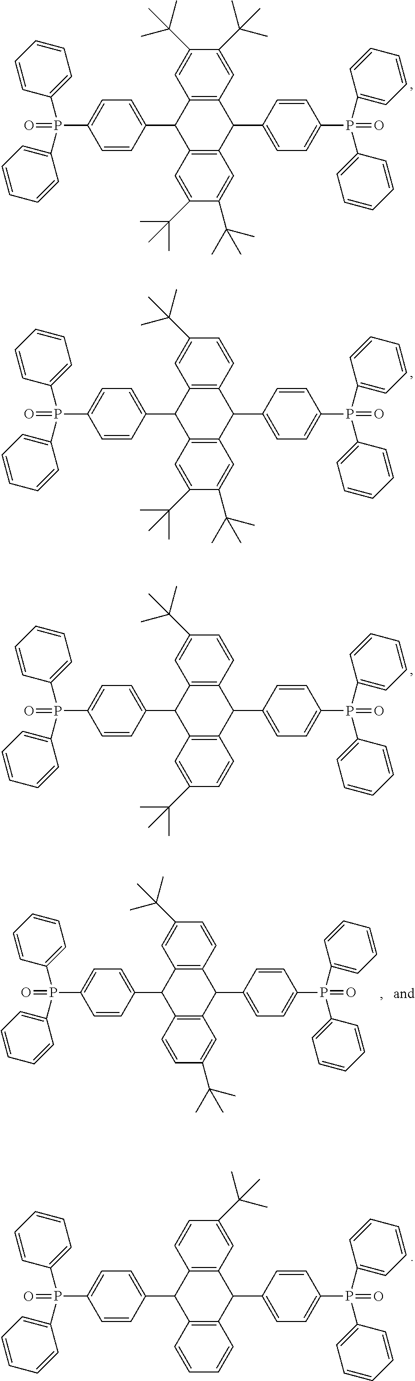

3. The method for manufacturing the electroluminescent material of claim 2, wherein the step of providing a first reactant and a second reactant, and reacting the first reactant and the second reactant in a first reaction solution to generate a first intermediate product, comprising:
providing a first reactant and a second reactant, and reacting the first reactant and the second reactant in a first reaction solution to generate a first mixture containing a first intermediate product; and
separating and purifying the mixture containing the first intermediate product, and then dissolving in a first solvent to obtain a second mixture containing the first intermediate product.

4. The method for manufacturing the electroluminescent material of claim 3, wherein in the step of providing a third reactant, and reacting the third reactant and the first intermediate product with an oxidant to generate the electroluminescent material, at a first temperature, a solution containing a catalyst is slowly added into the second mixture, then the third reactant is dropwise added, a reaction temperature is maintained below a second temperature, a stirring and reacting process is employed.

5. The method for manufacturing the electroluminescent material of claim 4, wherein the first temperature is −10 degrees Celsius to 150 degrees Celsius.

6. The method for manufacturing the electroluminescent material of claim 5, wherein the first temperature is −30 degrees Celsius to 100 degrees Celsius.

7. The method for manufacturing the electroluminescent material of claim 4, wherein the second temperature is 60 degrees Celsius.

8. The method for manufacturing the electroluminescent material of claim 3, wherein in the step of providing a third reactant, and reacting the third reactant and the first intermediate product with an oxidant to generate the electroluminescent material, a relationship between a molar quantity of the third reactant and a molar quantity of the first intermediate product is that for 2 millimoles-20 millimoles of the third reactant, there are 1 millimole-10 millimoles of the first intermediate product.

9. The method for manufacturing the electroluminescent material of claim 4, wherein in the step of providing a third reactant, and reacting the third reactant and the first intermediate product with an oxidant to generate the electroluminescent material, a relationship between a molar quantity of the third reactant and a molar quantity of the first intermediate product is that for 2 millimoles-20 millimoles of the third reactant, there are 1 millimole-10 millimoles of the first intermediate product.

10. The method for manufacturing the electroluminescent material of claim 3, wherein a relationship between a volume of the first solvent and a molar quantity of the first intermediate product is that for 10 milliliters-300 milliliters of the first solvent, there are 1 millimole-10 millimoles of the first intermediate product.

11. The method for manufacturing the electroluminescent material of claim 4, wherein a relationship between a volume of the first solvent and a molar quantity of the first intermediate product is that for 10 milliliters-300 milliliters of the first solvent, there are 1 millimole-10 millimoles of the first intermediate product.

12. The method for manufacturing the electroluminescent material of claim 3, wherein the first solvent is tetrahydrofuran.

13. The method for manufacturing the electroluminescent material of claim 4, wherein the first solvent is tetrahydrofuran.

14. The method for manufacturing the electroluminescent material of claim 3, wherein the first reaction solution comprises water.

15. The method for manufacturing the electroluminescent material of claim 4, wherein the first reaction solution comprises water.

16. The method for manufacturing the electroluminescent material of claim 3, wherein the solution containing the catalyst is a solution containing a catalyst n-BuLi.

17. The method for manufacturing the electroluminescent material of claim 4, wherein the solution containing the catalyst is a solution containing a catalyst n-BuLi.

18. Alight emitting device, comprising:
a substrate layer, wherein the substrate layer includes a base and an anode layer, the anode layer is formed on the base;
a hole injection layer, wherein the hole injection layer is formed on the anode layer;
a hole transport layer, wherein the hole transport layer is formed on the hole injection layer;
a light emitting layer, wherein the light emitting layer is formed on the hole transport layer;
an electron injection layer, wherein the electron injection layer is formed on the light emitting layer; and
a cathode layer, wherein the cathode layer is formed on the electron injection layer;
wherein the light emitting layer comprises the electroluminescent material, wherein a structural formula of the electroluminescent material comprises one of [chemical structure]
